(19) United States
(12) Patent Application Publication
(10) Pub. No.: US 2025/0327885 A1
(43) Pub. Date: Oct. 23, 2025

(54) MAGNETIC SENSOR CIRCUIT

(71) Applicant: ABLIC Inc., Nagano (JP)

(72) Inventors: Toshiyuki TSUZAKI, Nagano (JP); Taisuke ISHIZAWA, Nagano (JP)

(73) Assignee: ABLIC Inc., Nagano (JP)

(21) Appl. No.: 19/021,102

(22) Filed: Jan. 14, 2025

(30) Foreign Application Priority Data
Mar. 19, 2024 (JP) 2024-043822
Sep. 30, 2024 (JP) 2024-170208

(51) Int. Cl. G01R 33/07; G01R 33/00

(52) U.S. Cl. CPC G01R 33/075; G01R 33/0029

(57) ABSTRACT

A magnetic sensor circuit 100 includes: a Hall element 111, outputting a Hall voltage VH and an offset voltage VHos; a switch unit 120, setting the Hall voltage VH as an AC component and the offset voltage VHos as a DC component; a first DC cut filter 130, allowing the Hall voltage VH of the AC component to pass through and cutting off the offset voltage VHos of the DC component, and setting, to a predetermined common-phase voltage V3C, a common-phase voltage V2C; an amplifier circuit, amplifying a voltage in which an offset voltage VAMPos to the Hall voltage; a demodulation circuit, demodulating the Hall voltage VH of the AC component and modulating the offset voltage VAMPos of the DC component; and a low pass filter 160, allowing the Hall voltage VH of the DC component and cutting off the offset voltage VAMPos of the AC component.

### CROSS-REFERENCE TO RELATED APPLICATION

This application claims the priority benefit of Japan application serial no. 2024-043822, filed on Mar. 19, 2024 and Japan application serial no. 2024-170208, filed on Sep. 30, 2024. The entirety of each of the above-mentioned patent applications is hereby incorporated by reference herein and made a part of this specification.

### BACKGROUND

### Technical Field

The present invention relates to a magnetic sensor circuit.

### Description of Related Art

Various types of magnetoelectric conversion methods are provided for converting magnetic fields into voltage, but a Hall element is a representative example for semiconductor devices.

A Hall element utilizes the Hall effect and is a magnetoelectric conversion element that outputs a differential voltage proportional to the strength of the applied magnetic field. To operate the Hall element as a magnetic sensor, for example, a peripheral circuit such as a drive circuit and an amplifier circuit are connected to the Hall element.

The drive circuit includes a constant current source or a constant voltage source, and applies a constant current or a constant voltage to the Hall element to cause a drive current to flow. Additionally, since the Hall voltage output from the Hall element is very small, an amplifier circuit is connected to a subsequent stage of the Hall element.

Various solutions have been proposed for such peripheral circuit to perform high-precision magnetic detection. For example, a drive circuit has been proposed that controls the Hall element voltage by using an operational amplifier and suppresses temperature changes in the common-phase output voltage of the Hall element (see Japanese Patent Application Laid-open No. 2000-97972).

An aspect of the present invention aims to provide a magnetic sensor circuit that can suppress changes in the common-phase output voltage of the Hall element due to temperature while reducing current consumption, as well as enhancing magnetic detection accuracy.

### SUMMARY

A magnetic sensor circuit according to an embodiment of the present invention includes: a Hall element, through which a drive current flows by using a drive circuit, and which outputs a Hall voltage and a first offset voltage; a spinning circuit, based on a clock signal, changing a polarity that causes the drive current to flow, setting the Hall voltage as a DC component, setting the first offset voltage as an AC component, and outputting the first offset voltage; a modulation circuit, based on the clock signal, setting the Hall voltage as an AC component in a differential voltage output from the spinning circuit, and setting the first offset voltage as a DC component; a first DC cut filter, in a differential voltage output from the modulation circuit, allowing the Hall voltage as the AC component to pass through and cutting off the first offset voltage as the DC component, and setting, to a predetermined common-phase voltage, a common-phase voltage from the modulation circuit; an amplifier circuit, in a differential voltage output from the first DC cut filter, amplifying a voltage in which a second offset as a DC component is added to the Hall voltage of the AC component; a demodulation circuit, in a differential voltage output from the amplifier circuit, demodulating and setting the Hall voltage as the AC component as a DC component, and demodulating the second offset voltage of the DC component as an AC component; and a low pass filter, in a differential voltage output from the demodulation circuit, allowing the Hall voltage as the DC component to pass through and cutting off the second offset voltage as the AC component.

### BRIEF DESCRIPTION OF THE DRAWINGS

FIG. 1 is a block diagram illustrating a magnetic sensor circuit according to an embodiment of the present invention.

FIG. 2 is a circuit diagram illustrating a Hall sensor unit and a modulation circuit illustrated in FIG. 1.

FIG. 3 is a block diagram illustrating a magnetic sensor circuit in a modified example according to the embodiment illustrated in FIG. 1.

### DESCRIPTION OF THE EMBODIMENTS

A magnetic sensor circuit according to an embodiment of the present invention includes: a Hall element, through which a drive current flows by using a drive circuit, and which outputs a Hall voltage and a first offset voltage; a spinning circuit, based on a clock signal, changing a polarity that causes the drive current to flow, setting the Hall voltage as a DC component, setting the first offset voltage as an AC component, and outputting the first offset voltage; a modulation circuit, based on the clock signal, setting the Hall voltage as an AC component in a differential voltage output from the spinning circuit, and setting the first offset voltage as a DC component; a first DC cut filter, in a differential voltage output from the modulation circuit, allowing the Hall voltage as the AC component to pass through and cutting off the first offset voltage as the DC component, and setting, to a predetermined common-phase voltage, a common-phase voltage from the modulation circuit; an amplifier circuit, in a differential voltage output from the first DC cut filter, amplifying a voltage in which a second offset as a DC component is added to the Hall voltage of the AC component; a demodulation circuit, in a differential voltage output from the amplifier circuit, demodulating and setting the Hall voltage as the AC component as a DC component, and demodulating the second offset voltage of the DC component as an AC component; and a low pass filter, in a differential voltage output from the demodulation circuit, allowing the Hall voltage as the DC component to pass through and cutting off the second offset voltage as the AC component.

According to an aspect of the present invention, a magnetic sensor circuit can be provided. The magnetic sensor circuit can suppress changes in the common-phase output voltage of the Hall element due to temperature while reducing current consumption, as well as enhancing magnetic detection accuracy.

The present invention is based on the understanding that in the drive circuit using an operational amplifier as in Japanese Patent Application Laid-open No. 2000-97972, in the case where high-speed switching is performed to remove various offset voltages (unbalanced voltages), the operational amplifier is required to have quick responsiveness, resulting in increased current consumption. While it is considered that the drive circuit as in Japanese Patent Application Laid-open No. 2000-97972 can suppress temperature changes of the common-phase voltage of the Hall element, in the case where an operational amplifier is used in the drive circuit connected to the Hall element, the operational amplifier needs to respond to instantaneous voltage fluctuations, and a large current consumption is required for the operational amplifier.

A Hall element detects a magnetic field by the Hall voltage generated at a pair of opposing edges if a drive current is applied to another pair of edges orthogonal to the pair of opposing edges in a square non-magnetic metal layer formed on a silicon substrate. The Hall element is prone to generating an undesired offset voltage that affects magnetic detection accuracy.

The offset voltage of the Hall element is a voltage output from the Hall element in the case where no external magnetic field is applied to the Hall element, and is caused by factors such as the piezo effect due to a stress or manufacturing variations. The spinning current method is known as a method for removing such offset voltage. The spinning current method is a method for removing the offset voltage based on the output voltage in the case where the direction in which the drive current flows is changed by high-speed switching (in the case where the polarity is changed by) 90°. The spinning current method is always performed while operating the Hall element, as the Hall voltage does not change even in the case where the polarity is changed by 90°.

Even if the offset voltage of the Hall element is removed by the spinning current method, the offset voltage of the operational amplifier in the amplifier circuit that amplifies the differential voltage signal of the Hall element affects the magnetic detection accuracy.

The offset voltage of the operational amplifier is the differential voltage output from the operational amplifier in the case where no differential voltage signal is input to the operational amplifier, divided by the gain of the operational amplifier. The chopping method is known as a method for removing the offset voltage of the operational amplifier. The chopping method is a method of arranging a modulation circuit, an operational amplifier, a demodulation circuit, and a low pass filter in this order, thereby modulating, by using the demodulation circuit, the offset voltage of the operational amplifier located at a subsequent stage of the modulation circuit, and removing, by using the low pass filter, the offset voltage as an AC component.

In this way, when attempting to remove various offset voltages by performing the spinning current method and the chopping method, instantaneous voltage fluctuations occur in the Hall element due to high-speed switching. Thus, in the case where the operational amplifier is used in the drive circuit connected to the Hall element, the operational amplifier needs to respond to instantaneous voltage fluctuations, and a large current consumption is required for the operational amplifier.

Thus, in the magnetic sensor circuit according to an embodiment of the present invention, without using an operational amplifier in the drive circuit, a Hall element, a modulation circuit, a “DC cut filter”, an operational amplifier, a demodulation circuit, and a low pass filter are arranged in this order. As a result, the magnetic sensor circuit can remove various offset voltages by using the spinning current method and the chopping method without increasing current consumption. Thus, changes in the common-phase output voltage of the Hall element due to temperature can be suppressed, and magnetic detection accuracy can be increased.

The following describes in detail the embodiments for implementing the present invention with reference to the drawings.

In the drawings, the same reference numerals are assigned to the same components, and duplicate explanations may be omitted.

### EMBODIMENT

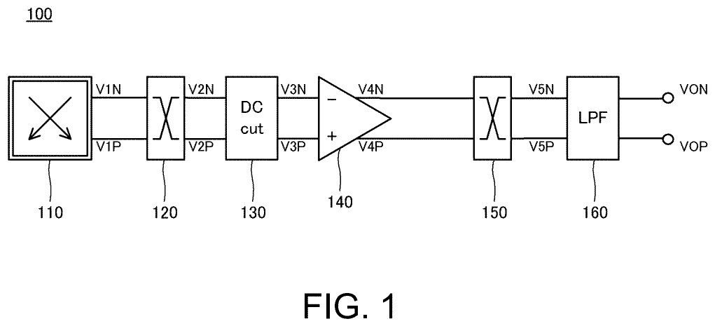

FIG. 1 is a block diagram illustrating a magnetic sensor circuit according to an embodiment of the present invention.

A magnetic sensor circuit 100 is a circuit that performs magnetic detection by using a Hall element and is formed by performing a semiconductor process.

As illustrated in FIG. 1, the magnetic sensor circuit 100 includes a Hall sensor unit 110 that performs magnetoelectric conversion using a Hall element, a switch unit 120, a DC cut filter 130, an amplifier circuit 140, a demodulation circuit 150, and a low pass filter 160.

The DC cut filter 130 may be referred to as a first DC cut filter.

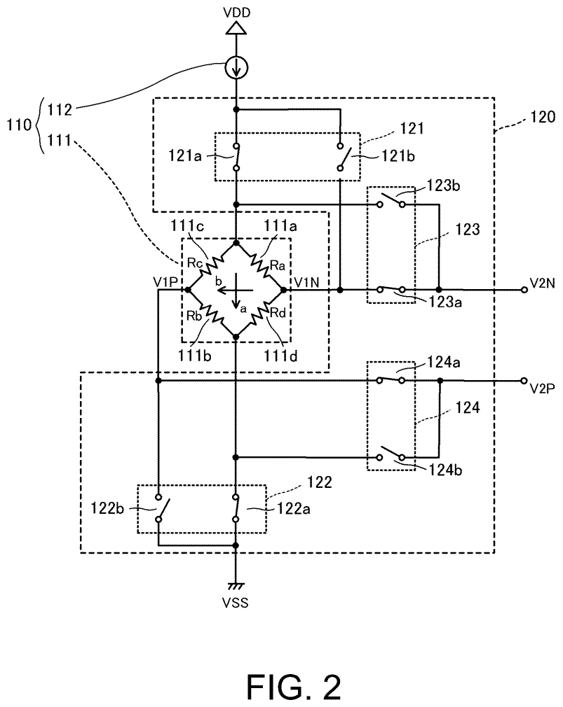

FIG. 2 is a circuit diagram illustrating the Hall sensor unit and the modulation circuit illustrated in FIG. 1.

As illustrated in FIG. 2, the Hall sensor unit 110 includes a Hall element 111 and a drive circuit 112.

### <Hall Element>

The Hall element 111 is a magnetoelectric conversion element that outputs a Hall voltage proportional to the strength of an external magnetic field when the external magnetic field is applied. The equivalent circuit of the Hall element 111 is a bridge circuit formed by four resistors 111a to 111d. Since resistance values Ra to Rd of the four resistors 111a to 111d change respectively due to temperature changes, the Hall voltage varies with temperature. In addition to the Hall voltage, the voltage signal of the Hall element 111 includes an offset voltage (first offset voltage) caused by the piezo effect due to stress or manufacturing variations.

Thus, if the polarity of the drive current (direction of flow of the drive current) of the Hall element 111 is indicated by an arrow a in FIG. 2, voltage signals VIP and VIN are expressed by Equations (1) and (2) as follows.

$$V 1 P = I \times ( R b \times Rd ) / ( Rb + R d ) + VH / 2 + VHos / 2 \qquad ( 1 )$$

$$V 1 N = I \times ( R b \times Rd ) / ( Rb + R d ) - VH / 2 - VHos / 2 \qquad ( 2 )$$

Here, I is a drive current flowing through the Hall element 111, VH is a Hall voltage output in proportion to the strength of the external magnetic field, and VHos is an offset voltage of the Hall element 111.

A differential voltage VID output from the Hall element 111 is represented by Equation (3) using Equations (1) and (2) above.

$$V 1 D = V 1 P - V 1 N = VH + VHos \qquad ( 3 )$$

A common-phase voltage VIC output from the Hall element 111 is the average voltage of the voltage signals VIP and VIN, and is thus represented by Equation (4) as follows.

$$V 1 C = ( V 1 P - V 1 N ) / 2 = [ I \times ( R b \times Rd ) / ( Rb + R d ) ] / 2 \qquad ( 4 )$$

Consequently, the common-phase voltage VIC depends on the resistance values Rb and Rd of the resistors 111b and 111d, and thus changes according to temperature.

### <Drive Circuit>

The drive circuit 112 is a constant current source using a current mirror circuit, and a drive current for generating the Hall effect flows to the Hall element 111, and the Hall element 111 is driven with a constant current.

The switch unit 120 has a function of, through high-speed switching based on a clock signal, changing the polarity by 90° in the spinning current method and modulating the Hall voltage of the Hall element in the chopping method. The switch unit 120 includes two switch pairs, which are spinning circuits 121 and 122, and two other switch pairs, which are modulation circuits 123 and 124.

The four switch pairs for the spinning circuits 121, 122 and the modulation circuits 123, 124 are connected to the connection units of the four resistors 111a to 111d of the Hall element 111, respectively. The four switch pairs include switches 121a, 122a, 123a, 124a that are turned ON at the L level of the clock signal, and switches 121b, 122b, 123b, 124b that are turned OFF at the L level of the clock signal. Additionally, in the four switch pairs, the switches 121a, 122a, 123a, 124a are turned OFF and the switches 121b, 122b, 123b, 124b are turned ON at a H level of the clock signal.

By switching the four switch pairs, the polarity of the drive current flowing from the drive circuit 112 to the Hall element 111 is changed, and the voltage signal of the Hall element 111 is modulated. At this time, in a the differential voltage signal of the Hall element 111, the Hall voltage VH does not change even if the polarity of the drive current is changed, and the offset voltage VHos is modulated.

The following description is divided into the spinning circuits 121, 122 and the modulation circuits 123, 124, using Equations (5) to (7).

### <Spinning Circuit>

The spinning circuits 121, 122 change the polarity of the drive current flowing in the Hall element 111 at the timing of a predetermined clock signal along the arrow a and an arrow b in FIG. 2, and output the Hall voltage VH as a DC component and the offset voltage VHos as an AC component. Thus, the differential voltage VID in the case where the polarity of the drive current changes becomes Equation (5) as follows from Equation (3) in the case where the polarity of the drive current does not change as described above.

$$V 1 D = V 1 P - V 1 N = VH \pm VHos \qquad ( 5 )$$

Here, “±” refers to an AC component.

### <Modulation Circuit>

The modulation circuits 123, 124, based on the clock signal, make the Hall voltage VH an AC component and the offset voltage VHos a DC component in the differential voltage output from the spinning circuits 121, 122.
Thus, in the case where a differential voltage V2D and a common-phase voltage V2C are output from the modulation circuits 123, 124, the differential voltage V2D and the common-phase voltage V2C are represented in Equations (6) and (7) as follows.

$$V 2 D = V 2 P - V 2 N = \pm V H \pm VHos \qquad ( 6 )$$

$$V 2 C = ( V 2 P - V 2 N ) / 2 = [ I \times ( R b \times Rd ) / ( Rb + R d ) ] / 2 \qquad ( 7 )$$

Due to the modulation circuits 123, 124, the differential voltage VID in Equation (5) becomes the differential voltage V2D in Equation (6), the Hall voltage VH is modulated to become an AC component, and the offset voltage VHos of the Hall element 111 becomes a DC component. The common-phase voltage V2C in Equation (7) is the same as the common-phase voltage VIC of the Hall element 111 as represented in Equation (4).

### <DC Cut Filter>

Referring to FIG. 1 again, the DC cut filter 130 is a high-pass filter with a capacitor connected in series, which cuts off the DC components of the voltage signals V2P and V2N from the modulation circuits 123 and 124, and outputs voltage signals V3P and V3N by allowing AC components to pass through.

Consequently, the differential voltage V3D and the common-phase voltage V3C are represented by Equations (8) and (9) as follows.

$$V 3 D = V 3 P - V 3 N = \pm VH \qquad ( 8 )$$

$$V 3 C = ( V 3 P - V 3 N ) / 2 = arbitrary common - phase voltage \qquad ( 9 )$$

With the DC cut filter 130, as the differential voltage V2D in Equation (6) becomes the differential voltage V3D in Equation (8), “+VHos” as the DC component of the differential voltage V2D is cut off, and the AC component of the differential voltage V2D passes through, resulting in “±VH”. In other words, even without using an operational amplifier in the drive circuit as in Japanese Patent Application Laid-open No. 2000-97972, the offset voltage VHos of the Hall element 111 can be removed by the DC cut filter 130, and the current consumption does not increase.

Furthermore, with the DC cut filter 130, while the common-phase voltage V2C in Equation (7) becomes the common-phase voltage V3C in Equation (9), a DC bias component can be added by using a constant voltage source in a subsequent stage of the DC cut filter 130. Thus, it is possible to set an arbitrary common-phase voltage. Moreover, since the resistance value of the equivalent resistance of the Hall element 111 is not included in Equation (9), it becomes less susceptible to the temperature change of the Hall element 111, and the temperature change at the common-phase voltage of the Hall element 111 can be suppressed.

### <Amplifier Circuit>

The amplifier circuit 140 differentially amplifies the voltage signals V3P and V3N from the DC cut filter 130 by using an operational amplifier, and outputs voltage signals V4P and V4N.

Thus, the differential voltage V4D and the common-phase voltage V4C can be expressed by Equations (10) and (11) as follows, if A is set as a gain of the operational amplifier in the amplifier circuit 140, and VAMPos is set as an offset voltage (second offset voltage) of the operational amplifier in the amplifier circuit 140.

$$V 4 D = V 4 P - V 4 N = \pm A \times V H + A \times VAMPos \qquad ( 10 )$$

$$V 4 C = ( V 4 P - V 4 N ) / 2 = arbitrary common - phase voltage \qquad ( 11 )$$

With the amplifier circuit 140, the differential voltage V3D in Equation (8) becomes the differential voltage V4D in Equation (10), whereas the DC component of the offset voltage VAMPos of the operational amplifier is added to the Hall voltage as the AC component, and both components are respectively amplified by A times.

### <Demodulation Circuit>

The demodulation circuit 150 demodulates the voltage signals V4P and V4N from the amplifier circuit 140 at the same timing of the predetermined clock signal same as the modulation circuits 123 and 124, and outputs voltage signals V5P and V5N.
Consequently, the differential voltage V5D and the common-phase voltage V5C are represented by Equations (12) and (13) as follows.

$$V 5 D = V 5 P - V 5 N = \pm A \times V H \pm A \times VAMPos \qquad ( 12 )$$

$$V 5 C = ( V 5 P - V 5 N ) / 2 = arbitrary common - phase voltage \qquad ( 13 )$$

With the demodulation circuit 150, the differential voltage V4D in Equation (10) becomes the differential voltage V5D in Equation (12), whereas the Hall voltage VH, which has been amplified A times, is demodulated to become a DC component, and the offset voltage VAMPos, which has been amplified A times, is modulated to become an AC component.

The common-phase voltage V5C in Equation (13) is the same as the common-phase voltage V4C of the Hall element 111 shown in Equation (11).

### <Low Pass Filter>

The low pass filter 160 outputs voltage signals VOP and VON in which the AC components of the voltage signals V5P and V5N from the demodulation circuit 150 are cut off.
Consequently, a differential voltage VOD and a common-phase voltage VOC are represented by Equations (14) and (15) as follows.

$$VOD = VOP - VON = A \times VH \qquad ( 14 )$$

$$VOC = ( VO P - V ON ) / 2 = arbitrary common - phase voltage \qquad ( 15 )$$

With the low pass filter 160, the differential voltage V5D in Equation (12) becomes the differential voltage VOD in Equation (14), +AxVAMPos as the AC component is cut off, and only the DC component of the Hall voltage VH of the Hall element 111 amplified A times remains. In this way, the offset voltage VAMPos as the AC component can be cut off by the low pass filter 160 in the subsequent stage using the chopping method.

The common-phase voltage VOC in Equation (15) is the same as the common-phase voltage V5C of the Hall element 111 shown in Equation (13).

In this way, by using the DC cut filter 130, the magnetic sensor circuit 100 according to the embodiment can remove the offset voltage VHos of the Hall element 111 by using the spinning current method.

Furthermore, the magnetic sensor circuit 100 can set the AC component, which is the output of the DC cut filter 130, to an arbitrary common-phase voltage, thereby suppressing temperature changes in the common-phase voltage of the Hall element 111. Consequently, there is no increase in current consumption due to high-speed response of the operational amplifier in the drive circuit as described in Japanese Patent Application Laid-open No. 2000-97972.
Moreover, the magnetic sensor circuit 100 can remove the offset voltage of the operational amplifier in the amplifier circuit 140 by using the chopping method.

### Modified Example of Embodiment

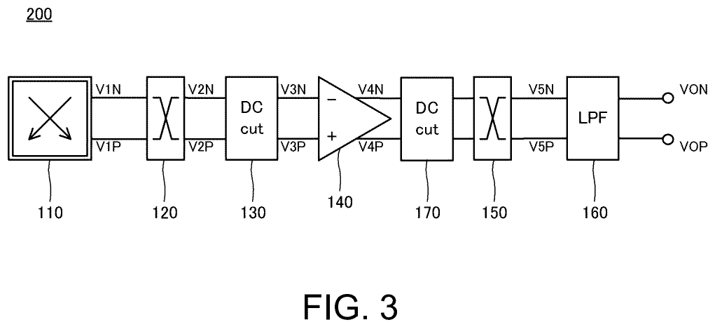

FIG. 3 is a block diagram illustrating a magnetic sensor circuit in a modified example according to the embodiment illustrated in FIG. 1.
As illustrated in FIG. 3, a magnetic sensor circuit 200 in the modified example is similar to the magnetic sensor circuit 100 shown in FIG. 1, except that a DC cut filter 170 is additionally connected between the amplifier circuit 140 and the demodulation circuit 150.
The DC cut filter 170 may be referred to as a second DC cut filter.
The magnetic sensor circuit 200 can further remove the offset voltage VHos of the Hall element 111 by using the DC cut filter 170.

As described above, in the magnetic sensor circuit according to an embodiment of the present invention, the Hall element, the modulation circuit, the DC cut filter, the operational amplifier, the demodulation circuit, and the low pass filter are arranged in this order. The Hall element outputs the Hall voltage and the offset voltage. By using the clock signal, the modulation circuit changes the polarity of the drive current and modulates the Hall voltage. The DC cut filter allows the Hall voltage as the AC component to pass through and cuts off the offset voltage as the DC component in the differential voltage from the modulation circuit, and can set the common-phase voltage from the modulation circuit to a predetermined common-phase voltage. The amplifier circuit amplifies the voltage in which the offset voltage of the operational amplifier is added to the Hall voltage. The demodulation circuit demodulates the Hall voltage as the AC component and modulates the offset voltage of the operational amplifier as the DC component. The low pass filter allows the Hall voltage as the DC component to pass through and cuts off the offset voltage of the operational amplifier as the AC component.

As a result, the magnetic sensor circuit can suppress the changes in the common-phase output voltage of the Hall element due to temperature while reducing current consumption, and can enhance magnetic detection accuracy.

The embodiment of the present invention has been described with reference to an example, but the present invention is not limited to the embodiment. Various modifications are possible within the scope of the present invention without departing from the spirit of the present invention.

For example, although a constant current source using a current mirror circuit is set as the drive circuit, for example, a constant current source or a constant voltage source without using an operational amplifier, or a constant current source or a constant voltage source connected so that the operational amplifier does not respond at high speed as in the spinning current method and the chopping method.
In addition, although a high-pass filter with a capacitor connected in series is used as the DC cut filter, the present invention is not limited thereto. Any filter capable of cutting off the DC component of the input voltage can be used.

What is claimed is:

1. A magnetic sensor circuit, comprising:
a Hall element, through which a drive current flows by using a drive circuit, and which outputs a Hall voltage and a first offset voltage;
a spinning circuit, based on a clock signal, changing a polarity that causes the drive current to flow, setting the Hall voltage as a DC component, setting the first offset voltage as an AC component, and outputting the first offset voltage;
a modulation circuit, based on the clock signal, setting the Hall voltage as an AC component in a differential voltage output from the spinning circuit, and setting the first offset voltage as a DC component;
a first DC cut filter, in a differential voltage output from the modulation circuit, allowing the Hall voltage as the AC component to pass through and cutting off the first offset voltage as the DC component, and setting, to a predetermined common-phase voltage, a common-phase voltage from the modulation circuit;
an amplifier circuit, in a differential voltage output from the first DC cut filter, amplifying a voltage in which a second offset as a DC component is added to the Hall voltage of the AC component;
a demodulation circuit, in a differential voltage output from the amplifier circuit, demodulating and setting the Hall voltage as the AC component as a DC component, and demodulating the second offset voltage of the DC component as an AC component; and
a low pass filter, in a differential voltage output from the demodulation circuit, allowing the Hall voltage as the DC component to pass through and cutting off the second offset voltage as the AC component.

2. The magnetic sensor circuit as claimed in claim 1, wherein the drive circuit is a constant current source using a current mirror circuit.

3. The magnetic sensor circuit as claimed in claim 1, wherein the second DC cut filter is connected between the amplifier circuit and the demodulation circuit.
